(19) United States
(12) Patent Application Publication
(10) Pub. No.: US 2010/0052143 A1
(43) Pub. Date: Mar. 4, 2010

(54) Electronic packaging structure and a manufacturing method thereof

(76) Inventors: Chung-ER Huang, Taipei (TW); MING-TAI KUO, TAIPEI (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 12/585,464

(22) Filed: Sep. 16, 2009

Related U.S. Application Data
(62) Division of application No. 12/230,531, filed on Aug. 29, 2008.

(51) Int. Cl. H01L 23/48

(52) U.S. Cl. 257/690; 257/E23.01

(57) ABSTRACT

A packaging structure includes a main substrate having a plurality of circuit lines thereon, and an electronic module having at least one conductive pad at the bottom thereof and having a plurality of conductive lines on the sides thereof. The pad and the conductive circuits are connected electrically to the circuits on the main substrate when the electronic module is disposed on the main substrate. As above-mentioned, one electronic module can be stacked on top of another so that the integrity of the packaging structure is improved.

### RELATED APPLICATIONS

This application is a Divisional patent application of co-pending application Ser. No. 12/230,531, filed on 29 Aug. 2008. The entire disclosure of the prior application, Ser. No. 12/230,531, from which an oath or declaration is supplied, is considered a part of the disclosure of the accompanying Divisional application and is hereby incorporated by reference.

### BACKGROUND OF THE INVENTION

1. Field of the Invention

The present invention relates to an electronic packaging structure and a manufacturing method thereof, more particularly the present invention relates to an electronic packaging structure that can be stacked with a high degree of integrity and a manufacturing method thereof.

2. Description of Related Art

With the development of the semiconductor technology, the function of the semiconductor chip became more and more powerful. The chip has more and more terminals to transmit the ever increasing processing data so that the packaging technique has to improve for packaging the chip into smaller and thinner volume. For meeting the requirement of the high module density, the module of electronic products such as laptop computers, mobile phones, or digital cameras have to perform with high reliability. Taking the mobile phone as an example, most of mobile phones are used for multi-media application that demands the processing of a large amount of processing data; however the size of the phone is still small enough for ease of carry. Thus how to save/compact the volume of modules is always the focal point for engineers and developers in this modern world.

When the number of modules became more and more, the area of substrate for carrying the modules can not be easily reduced. The traditional arrangement of the modules on the substrate is parallel and the modules can not be efficiently integrated.

Therefore, in view of this, the inventor proposes the present invention to overcome the above problems based on his expert experience and deliberate research.

### SUMMARY OF THE INVENTION

The primary object of the present invention is to provide an electronic packaging structure and a manufacturing method thereof. The electronic packaging structure has conductive lines on the sides of the electronic module so as to stack one electronic module on another.

In order to achieve the above object, the present invention provides a manufacturing method for an electronic packaging structure. The method comprises the following steps. Step 1 is providing an electronic module. Step 2 is forming a plurality of conductive lines on the sides of the electronic module. Step 3 is providing a main substrate having a plurality of circuit lines thereon; and step 4 is disposing the electronic module on the main substrate, wherein the conductive lines on the sides of the electronic module correspond to the circuit lines. Therefore, power or signals can “climb” (i.e. extend) from the main substrate onto a top surface of the electronic module.

The present invention still provides an electronic packaging structure. The structure comprises a main substrate and an electronic module. The main substrate has a plurality of circuit lines thereon. The electronic module has at least a conductive pad at a bottom thereof and a plurality of conductive lines on the sides thereof, and the conductive pad and the conductive lines electrically connect with the circuit lines.

The feature of the present invention is that the structure has conductive lines on the sides of the electronic module so that one electronic module can be placed on top of another and still allows to electrical connection. Therefore, the vertical stacking of the packaging structure is made possible and the degree of structure integrity is increased (i.e. made more compact). Moreover, the conductive lines on the module sides can perform as an alignment target and the operator can easily align the electronic module and monitor the welding process. Thus, the quality of welding is also improved.

In order to better understand the characteristics and technical contents of the present invention, a detailed description thereof will be made with reference to accompanying drawings. However, it should be understood that the drawings and the description are illustrative only and are not used to limit the scope of the present invention.

### BRIEF DESCRIPTION OF THE DRAWINGS

FIG. 1 shows the packaging structure of an electronic module according to the present invention.

FIG. 1A shows the bottom view of the packaging structure of an electronic module according to the present invention.

FIG. 1B shows that the packaging structure has conductive lines on the sides thereof according to the present invention.

FIG. 2 shows that the packaging structure of an electronic module is disposed on the main substrate according to the present invention.

FIG. 2A shows a side view of the packaging structure of an electronic module disposed on the main substrate according to the present invention.

FIG. 2B shows that an electronic device is disposed on the packaging structure of an electronic module according to the present invention.

FIG. 2C shows that another electronic module is disposed on the packaging structure of an electronic module according to the present invention.

### DETAILED DESCRIPTION OF PREFERRED EMBODIMENTS

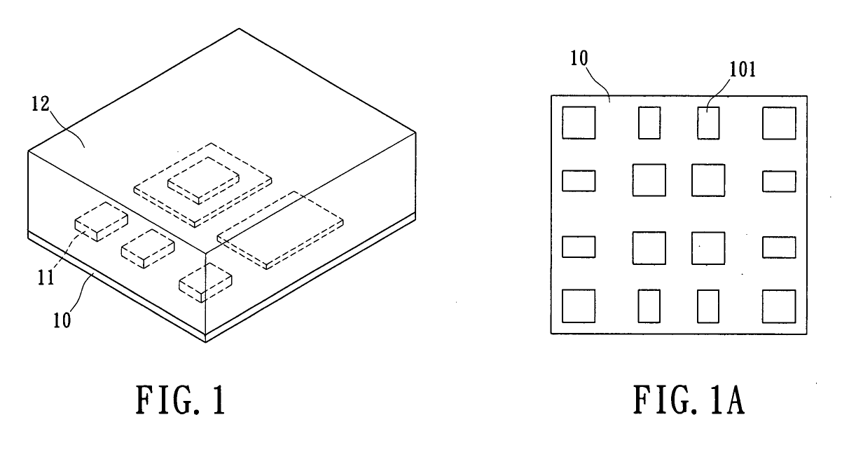

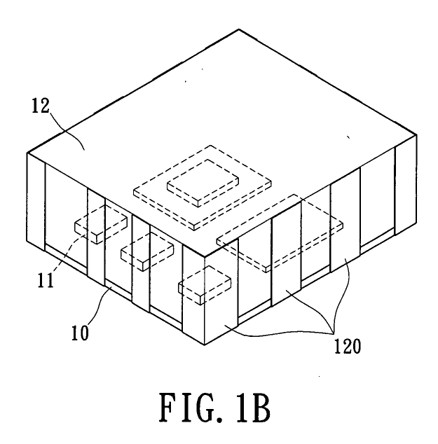

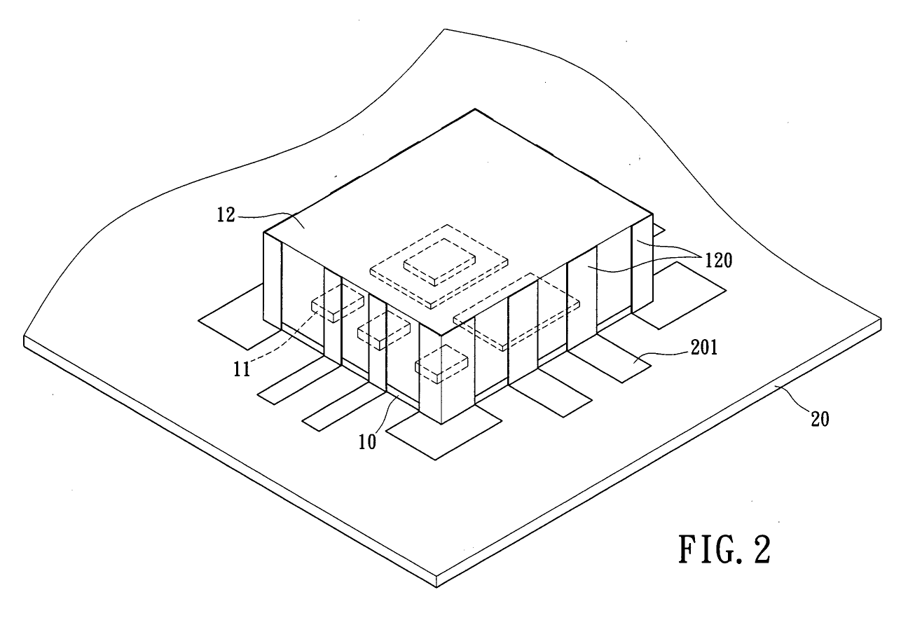

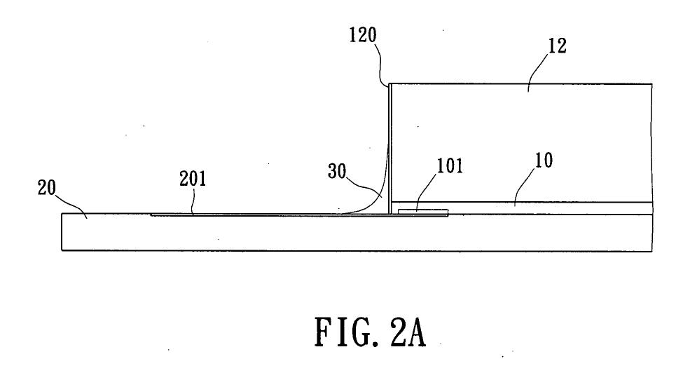

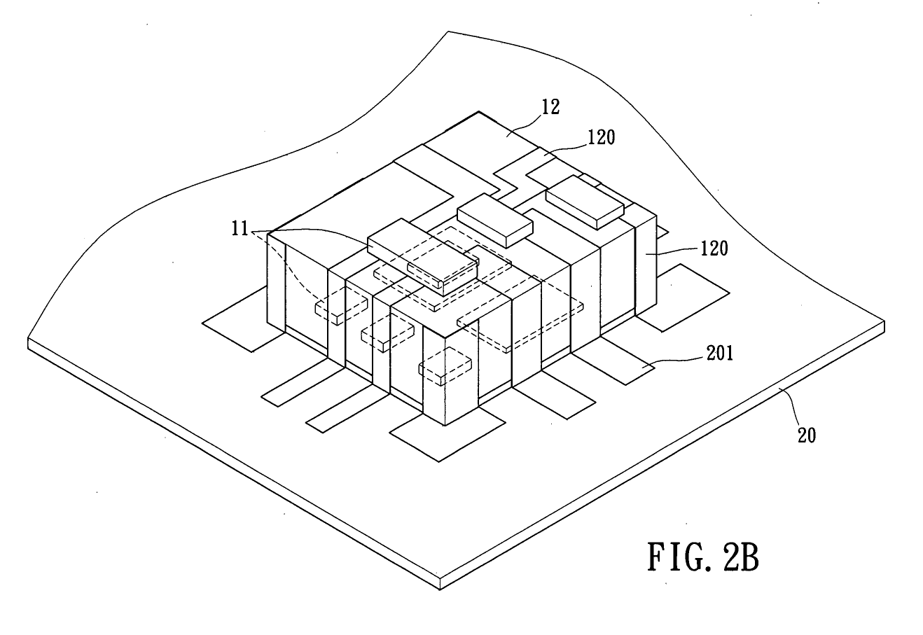

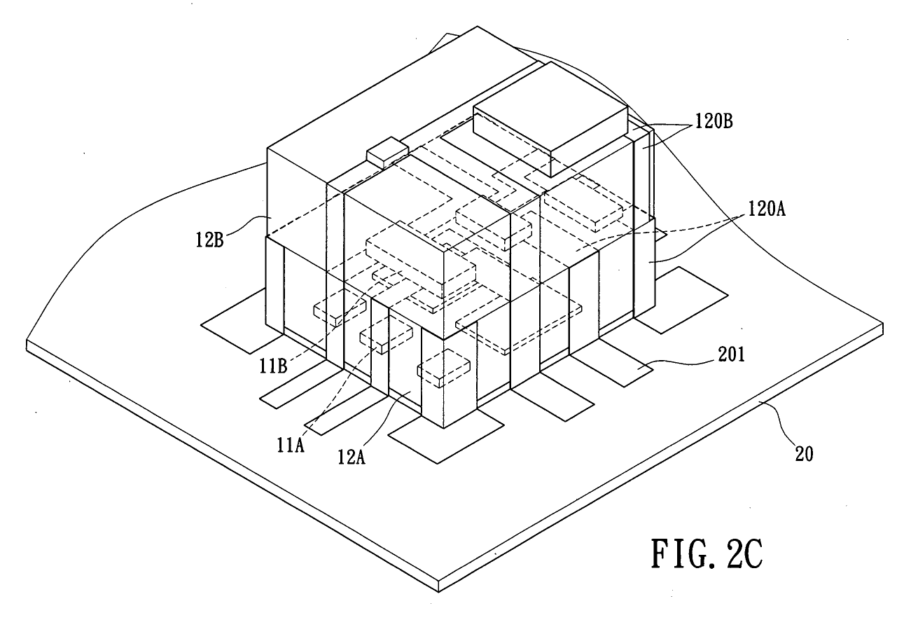

Please refer to FIG. 2; the present invention discloses an electronic packaging structure and a manufacturing method thereof. The manufacturing method is used for forming conductive lines on the sides of the module so that the modules can be stacked one on top of the other. Thus, the vertical circuit is achieved. Please refer to FIGS. 1 and 1A in conjunction to FIG. 2, the manufacturing method includes the following steps.

Step 1 is for providing an electronic module. The electronic module has a bottom surface shown in FIG. 1A, a top surface, and sides (i.e. left, right, front, and back sides) connecting between the top surface and the bottom surface. In the embodiment, the electronic module is substantially a rectangular box, but the shape of the electronic module is not restricted to this embodiment. The electronic module can be a Bluetooth module, wireless module, or another functional equivalent.

There are two methods for manufacturing the electronic module. One method has the following steps. Step A is disposing a plurality of electronic devices 11 on a substrate 10 and then step B is covering the electronic devices 11 by a packaging member 12 to form a plurality of the electronic modules. The packaging member 12 can be a cured resin. Step C, the connecting electronic modules are separated into individual and single electronic module by a cutting step.

The second method changes the sequence of step B and C. Thus, the first step of the second method is the same as the first method, i.e. step A is disposing a plurality of electronic devices 11 on a substrate 10 and then the electronic devices 11 are pre-packaged by a thinner pre-packaging layer (not shown). Step B is providing a cutting step to form individual and single electronic module pre-packaging layer. In this step, a punching method is applied for separating the individual and single electronic module with pre-packaging layer, and the size of the punched electronic module is precisely controlled. Step C, each of the individual electronic modules with pre-packaging layer is mainly packaged so as to form a packaging member 12 covering and protecting the electronic devices 11. Either of the two manufacturing method for an electronic module can be applied in the electronic packaging structure manufacturing method of the present invention.

The electronic module manufactured by the aforementioned methods has a substrate 10, at least one electronic device 11 disposed on the substrate 10, and a packaging member 12 covering the electronic device 11 as shown in FIG. 1. The electronic module has at least one conductive pad 101 at the bottom of the substrate 10 (shown in FIG. 1A), and the conductive pad 101 electrically connects with the electronic device 11 to transmit power or signals.

Step 2, please refer to FIG. 1B. Step 2 is the forming of a plurality of conductive lines 120 on sides of the electronic module. The feature of this step is forming the conductive lines 120 on the sides of the electronic module in order to transmit power or signals in vertical direction so that the electronic module can be disposed on top of another electronic module. The conductive lines 120 are formed on the sides of the electronic module by a coating method or a printing method.

Step 3 is providing a main substrate 20 and the main substrate 20 functions as a system substrate for carrying the electronic modules which cooperate together as an electronic system. The main substrate 20 has a plurality of circuit lines 201 thereon. It is well known in the industry how to manufacture the main substrate 20 and the circuit lines 201, and the manufacturing method is omitted.

Step 4, please refer to FIG. 2. Step 4 is disposing the electronic module on the main substrate 20. In this step, the conductive pad 101 will electrically contact the circuit lines 201 on the main substrate 20, and simultaneously the conductive lines 120 on the sides of the electronic module also electrically contact the circuit lines 201. The circuit design of the conductive pad 101, the conductive lines 120, and the circuit lines 201 can be adjusted according to the application. For example, the conductive pad 101 and the conductive lines 120 for the same signal will contact the same circuit lines 201.

The manufacturing method further has a welding step after step 4. The welding step is for welding each of the conductive lines 120 to the corresponding circuit line 201, therefore, a welding structure 30 (please refer to FIG. 2A) is formed at the corner between the electronic module and the main substrate 20. The welding structure 30 such as a welding point performs as a connection means for contacting the conductive lines 120 and the corresponding circuit line 201. Note that the welding structure 30 is only shown in FIG. 2A. In the same step, the conductive pad 101 can be welded to the corresponding circuit line 201. Further note that the conductive pad 101 does not directly contact the conductive lines 120.

After step 4, a plurality of auxiliary conductive lines (Note that conductive line 120 includes a primary conductive line and an auxiliary conductive line, wherein primary conductive line are on the side of the electronic module and auxiliary conductive lines are on the top of the electronic module) are formed on a top surface of the electronic module, and the auxiliary conductive lines on the top surface of the electronic module electrically connect to the primary conductive lines on the sides of the electronic module. In this step, the auxiliary conductive lines can be formed by a coating method or a printing method. Thus the auxiliary conductive lines are considered as an extension from the primary conductive lines on the sides of the electronic module (i.e. together, primary conductive line and auxiliary line forms the conductive line 120) and power and signals can be transmitted onto the top of the electronic module. It is believed that the top of the electronic module can be used as a specific platform on which another module or an electronic device can be disposed upon so that one electronic module can be stacked on top of another so as to increase the vertical integrity of the system.

Please refer to FIG. 2B, the electronic module has at least one electronic device 11 disposed on top and the electronic device connects electrically to the main substrate 20 through the auxiliary conductive lines of the conductive line 120 on the top of the electronic module.

Please refer to FIG. 2C; two electronic modules are stacked by the method of the present invention. The lower electronic module has a plurality of first electronic devices 11A which are covered by the first packaging member 12A. The first primary conductive lines and the first auxiliary conductive lines of the first conductive line 120A are respectively formed on the sides and the top surface of the lower module. Similarly, the upper electronic module has a plurality of second electronic devices 11B which are covered by the second packaging member 12B. The second primary conductive lines and the second auxiliary conductive lines of the second conductive lines 120B are respectively formed on the sides and the top surface of the upper module. The bottom of the upper module has conductive pads. When the upper electronic module is disposed on top of the lower one, the conductive pads of the upper electronic module connects electrically to the first auxiliary conductive lines of the first conductive lines 120A on the top surface of the lower module so that the upper electronic module can receive power or signals from the main substrate 20. Thereby, the second primary conductive lines and the second auxiliary conductive lines of the second conductive lines 120B couples electrically to the first primary conductive lines and the first auxiliary conductive lines so that power or signals can “climb” (i.e. extend) onto the top surface of the upper module. Therefore, a third module can be disposed on the top surface of the second module because of the vertical transmission.

By stacking the electronic modules, the footprint of the main substrate 20 (i.e. the occupied area of the main substrate 20) is reduced. Furthermore, the vertical integrity of the system is improved.

The present invention discloses an electronic packaging structure which comprises a main substrate 20 having a plurality of circuit lines 201 thereon; and an electronic module disposed on the main substrate 20. The electronic module has a substrate 10, at least on electronic device 11 on the substrate 10, and a packaging member 12 covering the electronic device 11. The electronic module has at least a conductive pad 101 at a bottom of the substrate 10 and a plurality of conductive lines 120 on the sides and top of the packaging member 12. The conductive pad 101 and the conductive lines 120 electrically connect with the circuit lines 201. Therefore, the electronic modules can be stacked on the main substrate 20 so as to improve the integrity.

To sum up, the present invention has the following advantages.

1. The primary conductive lines and the auxiliary conductive lines of the conductive lines are formed on the sides and the top of the electronic module so that power or signals can be transmitted in an upward direction so as to making stacking one functional electronic module on top of another functional electronic module possible, furthermore it is also possible to stack a electronic device on top of an electronic module. Therefore, the present invention can improve the vertical integrity of the system.

2. Because the module has conductive lines on sides thereof, the operator can easily see the connection between the conductive lines and the circuit lines during the welding process. While by the tradition method, there is no conductive line on the sides of the electronic module; so that when the modules are welded on the main substrate, only the conductive pads at the bottom of the module are used for connecting to the circuit lines. Therefore, the operator can not easily determine the conductive pads are aligned to the circuit lines or not. On the contrary, according to the present invention, by aligning the conductive lines to the circuit lines, the precision of the connection is achieved. Moreover, the operator can clearly monitor the melt situation of the soldering materials.

3. The method disclosed in the present invention can be fast and efficiently processed with another manufacturing step such as a multi-layer covering process and a circuit printing process. In other words, the method is capable of being used in a highly integrated process and is easy for optimization.

Although the present invention has been described with reference to the foregoing preferred embodiment, it shall be understood that the present invention is not limited to the details thereof. Various equivalent variations and modifications may occur to those skilled in this art in view of the teachings of the present invention. Thus, all such variations and equivalent modifications are also embraced within the scope of the present invention as defined in the appended claims.

What is claimed is:

1. An electronic packaging structure, comprising:
a main substrate, having a plurality of circuit lines thereon; and
an electronic module, having at least a conductive pad at the bottom thereof and a plurality of conductive lines on the sides thereof, wherein the conductive pad and the conductive lines electrically connect with the circuit lines.

2. The electronic packaging structure according to claim 1, wherein the electronic module further has a substrate, at least one electronic device disposed on the substrate, and a packaging member covering the electronic device.

3. The electronic packaging structure according to claim 2, wherein the conductive pad is disposed at the bottom of the substrate and the conductive lines are formed on the sides of the packaging member.

4. The electronic packaging structure according to claim 3, wherein the conductive lines extend from the sides of the packaging member to the top surface of the packaging member of the electronic module to form a plurality of auxiliary conductive lines on the top surface of the electronic module.

5. The electronic packaging structure according to claim 4, further comprising at least one electronic device disposed on the top surface of the electronic module, wherein said electronic device electrically connects to the auxiliary conductive lines.

6. The electronic packaging structure according to claim 4, further comprising another electronic module stacked on the top surface of the electronic module, wherein the second electronic module electrically connects with the auxiliary conductive lines and the another electronic module has a plurality of conductive lines on the sides thereof.
